(19) United States
(12) Patent Application Publication
(10) Pub. No.: US 2023/0251308 A1
(43) Pub. Date: Aug. 10, 2023

(54) SOCKET AND INSPECTION SOCKET

(71) Applicant: Enplas Corporation, Saitama (JP)

(72) Inventor: Hiroyuki ICHIKAWA, Saitama (JP)

(73) Assignee: Enplas Corporation, Saitama (JP)

(21) Appl. No.: 17/766,806

(22) PCT Filed: Oct. 7, 2020
(86) PCT No.: PCT/JP2020/037934

§ 371 Date: Apr. 6, 2022

(30) Foreign Application Priority Data
Oct. 10, 2019 (JP) 2019-186555

(51) Int. Cl. G01R 31/28; G01R 1/04; H01R 13/10; H01R 13/24

(52) U.S. Cl. CPC G01R 31/2886; G01R 1/0466; H01R 13/10; H01R 13/2407; H01R 13/502

(57) ABSTRACT

This socket is provided with: an accommodating section having a recess capable of accommodating an electronic component; an opening/closing section for opening/closing an opening of the recess and pressing the electronic component in the recess in a direction of pressing when the opening is in a closed position; and a support section for supporting the opening/closing section so as to be able to move between an open position and the closed position. The support section supports the opening/closing section, in a closing operation of the opening/closing section, so that the opening/closing section moves while changing the angle formed with the direction of pressing as the opening/closing section moves from the open position to a predetermined position ahead of the closed position, and so that the opening/closing section moves along the direction of pressing when the opening/closing section moves from the predetermined position to the closed position.

### TECHNICAL FIELD

The present invention relates to a socket and a socket for inspection (hereinafter also referred to as “inspection socket”).

### BACKGROUND ART

As a socket used for housing an electronic component, such as an integrated circuit (IC), for electrical connection with the outside, an IC socket, for example, has been known. IC sockets are used to inspect the electrical characteristics of electronic components when the components are inspected for shipping. Such a socket typically has a configuration such that the electronic component is pressed for electrically connecting the socket to the electronic component without fail. For example, a socket in Patent Literature (hereinafter, referred to as PTL) 1 has a configuration such that a cam member presses an IC package via a pressing block (see FIGS. 1 and 2 of PTL 1).

### CITATION LIST

### Patent Literature

PTL 1
Japanese Patent Application Laid-Open No. H11-26124

### SUMMARY OF INVENTION

### Technical Problem

In the pressing method using a cam member as described above, the cam member is rotated to press a pressing block. Therefore, as the cam member rotates, a force is also applied in the direction along the surface of the pressing block to possibly shift the pressing block in the applied direction. A shifted pressing block may rub the surface of an IC package to damage the IC package.

An object of the present invention is to provide a socket and an inspection socket capable of reducing the possibility of damaging an electronic component during the pressing of the electronic component.

### Solution to Problem

A socket according to the present invention includes:

a housing part including a recess configured to house an electronic component;

an opening/closing part that opens and closes an opening of the recess, and presses the electronic component in the recess in a pressing direction when the opening/closing part is in a closed position; and

a supporting part that supports the opening/closing part so as to allow a movement of the opening/closing part between an opened position and the closed position,

in which

during a closing operation of the opening/closing part, the supporting part supports the opening/closing part in such a way that
when the opening/closing part moves from the opened position to a predetermined position located before the closed position, the movement of the opening/closing part is accompanied by changing of an angle between the pressing direction and the opening/closing part, and
when the opening/closing part moves from the predetermined position to the closed position, the movement of the opening/closing part is along the pressing direction.

An inspection socket according to the present invention includes:

the above described socket; and

a contact part disposed in a bottom portion of the recess, the contact part being configured to be electrically connected to the electronic component in the recess, wherein
the inspection socket is used for inspecting electrical characteristics of the electronic component.

### Advantageous Effects of Invention

The present invention can reduce the possibility of damaging an electronic component during the pressing of the electronic component.

### BRIEF DESCRIPTION OF DRAWINGS

FIG. 1 is a perspective view of a socket according to an embodiment of the present invention in a closed position;

FIG. 2 is a top view of the socket illustrated in FIG. 1 in the closed position;

FIG. 3 is a perspective view of the socket illustrated in FIG. 1 in the opened position;

FIG. 4 is a cross-sectional view taken along the line A-A of FIG. 2;

FIG. 5 is a cross-sectional view taken along the line B-B of FIG. 2;

FIG. 6A is a cross-sectional view taken along line C-C of FIG. 2, and illustrating the socket with an opening degree of 100° (in the opened position);

FIG. 6B is a cross-sectional view taken along line D-D of FIG. 2, and illustrating the socket with the opening degree of 100° (in the opened position);

FIG. 6C is a side view of the socket with the opening degree of 100°;

FIG. 7A is a cross-sectional view taken along line C-C of FIG. 2, and illustrating the socket with the opening degree of 6°;

FIG. 7B is a cross-sectional view taken along line D-D of FIG. 2, and illustrating the socket with the opening degree of 6°;

FIG. 7C is a side view of the socket with the opening degree of 6°;

FIG. 8A is a cross-sectional view taken along line C-C of FIG. 2, and illustrating the socket with the opening degree of 0° (in the closed position);

FIG. 8B is a cross-sectional view taken along line D-D of FIG. 2, and illustrating the socket with the opening degree of 0° (in the closed position); and

FIG. 8C is a side view of the socket with the opening degree of 0°.

### DESCRIPTION OF EMBODIMENTS

Hereinafter, a socket according to an embodiment of the present invention will be described in detail with reference to the drawings. Herein, an inspection socket is exemplified as the socket; however, the present invention is applicable to any socket as long as the socket is for housing an electronic component for electrical connection with the outside.

Configuration of Inspection Socket

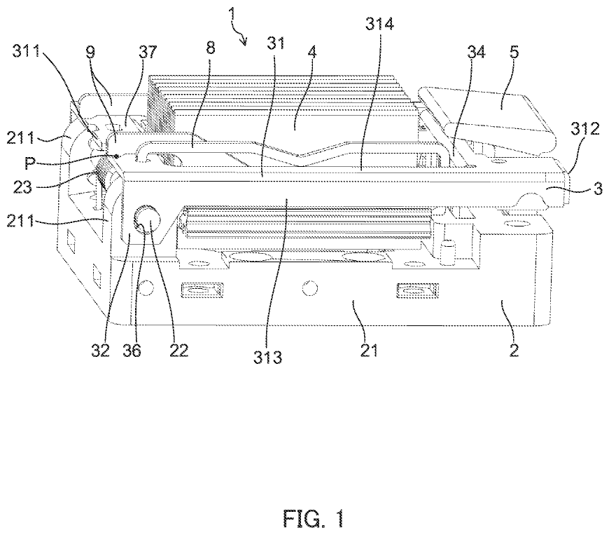

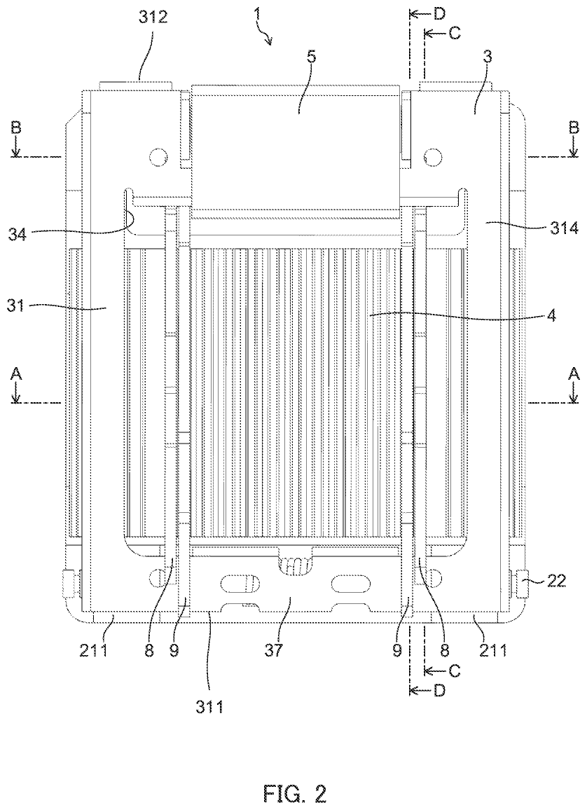

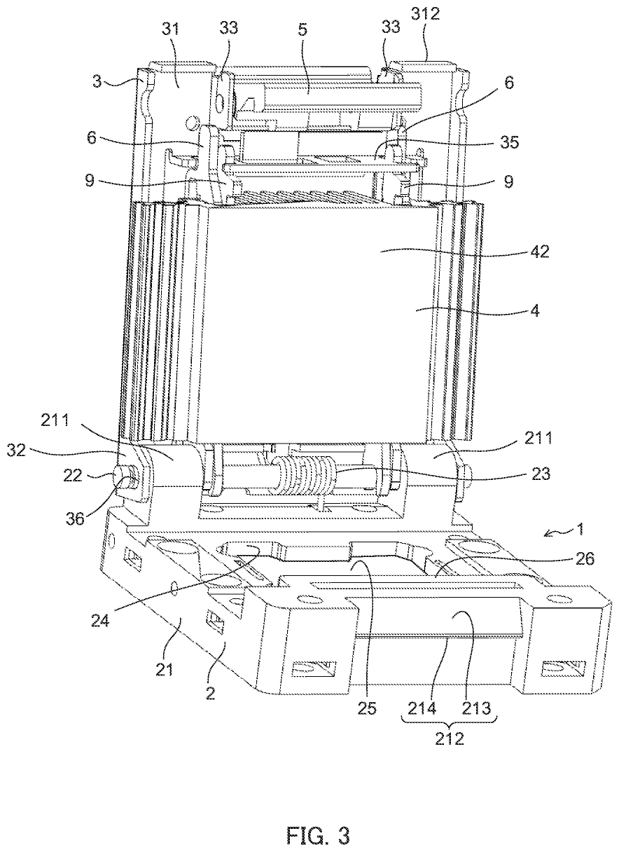

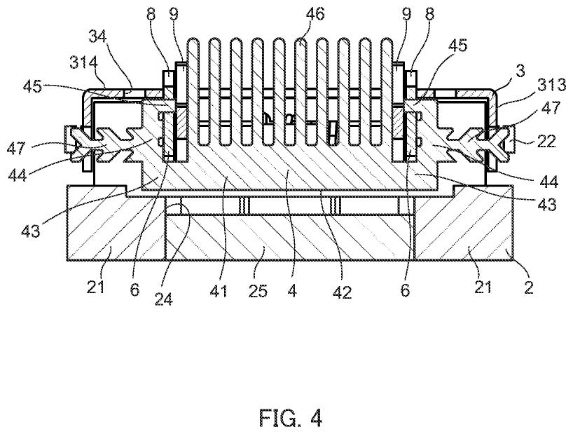

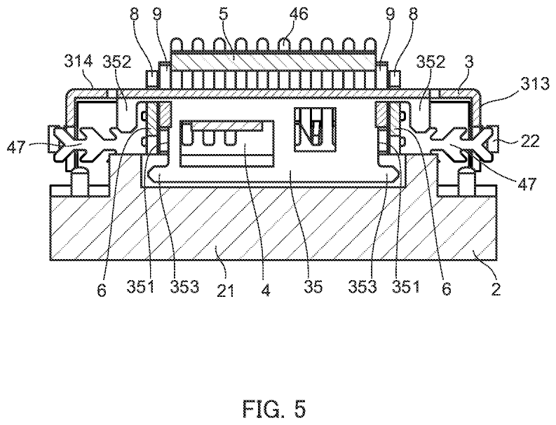

FIG. 1 is a perspective view of inspection socket 1 according to the present embodiment in a closed position; FIG. 2 is a top view of the socket in the closed position; and FIG. 3 is a perspective view of the socket in an opened position. FIG. 4 is a cross-sectional view taken along the line A-A of FIG. 2; and FIG. 5 is a cross-sectional view taken along the line B-B of FIG. 2.

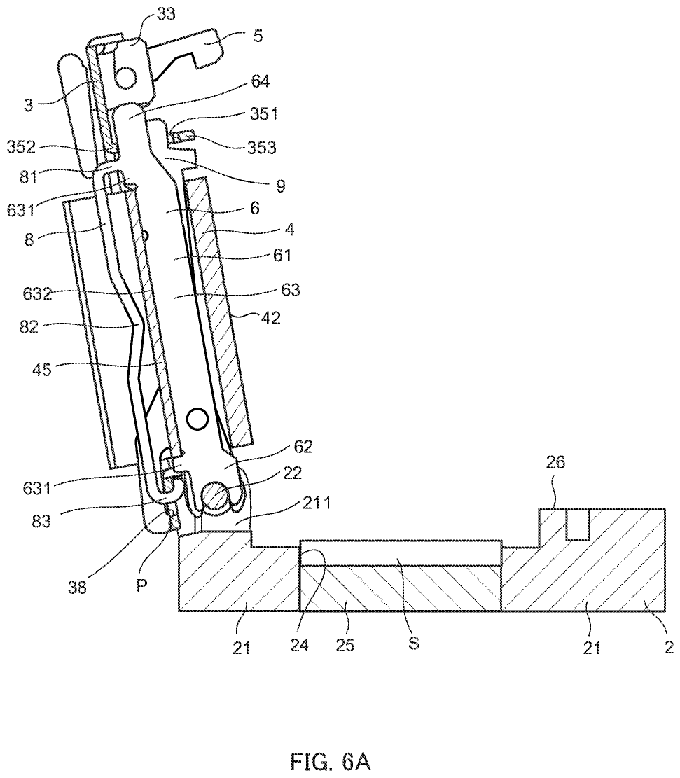

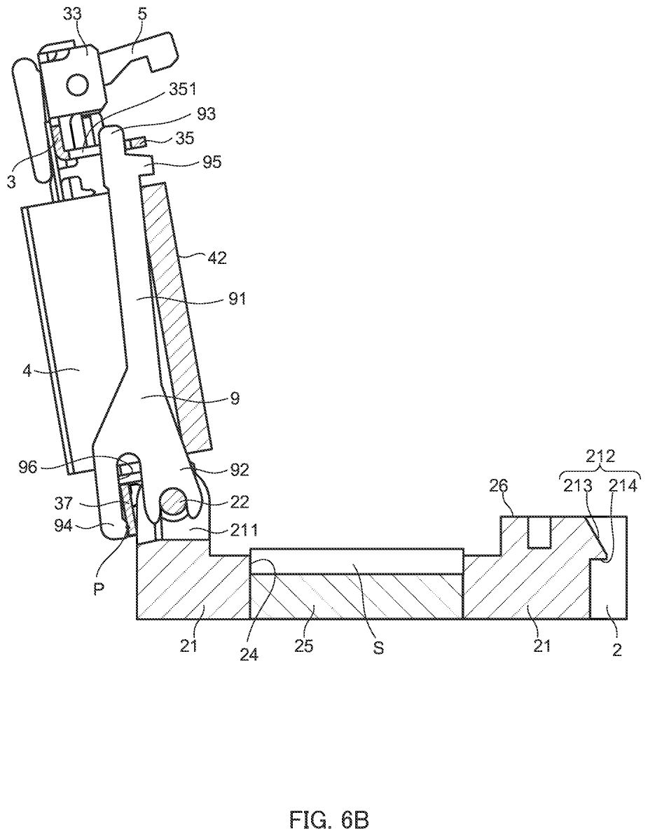

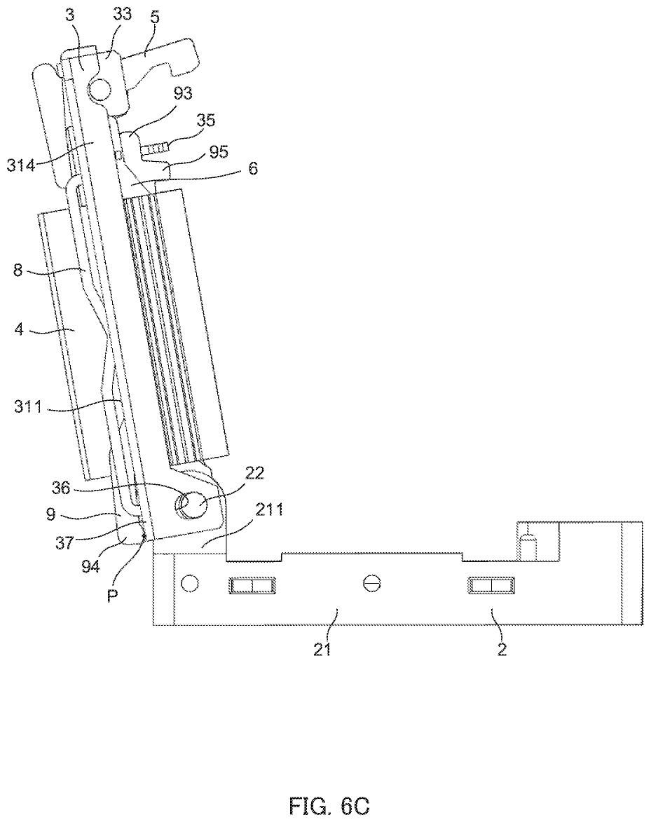

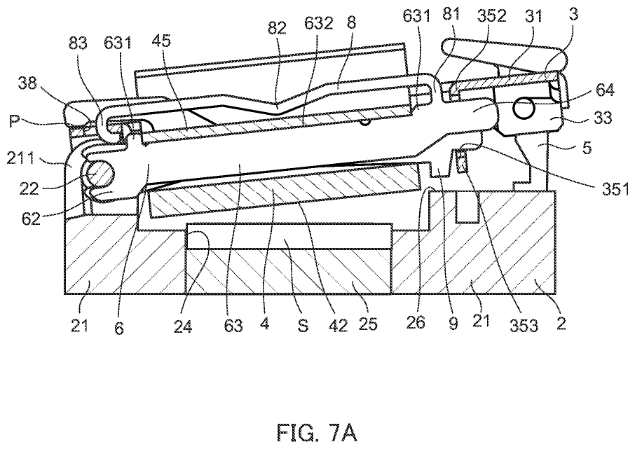

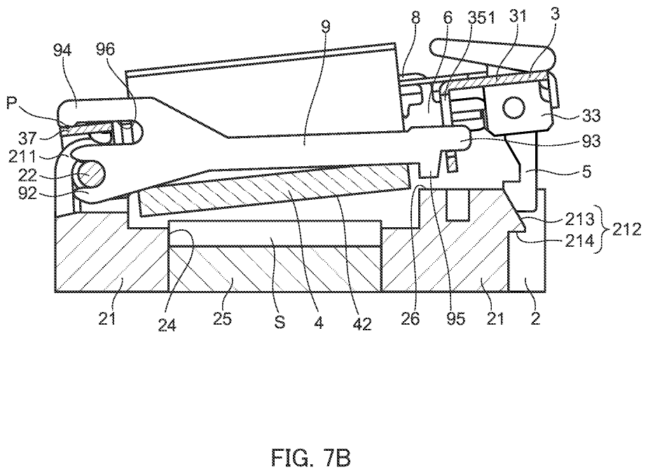

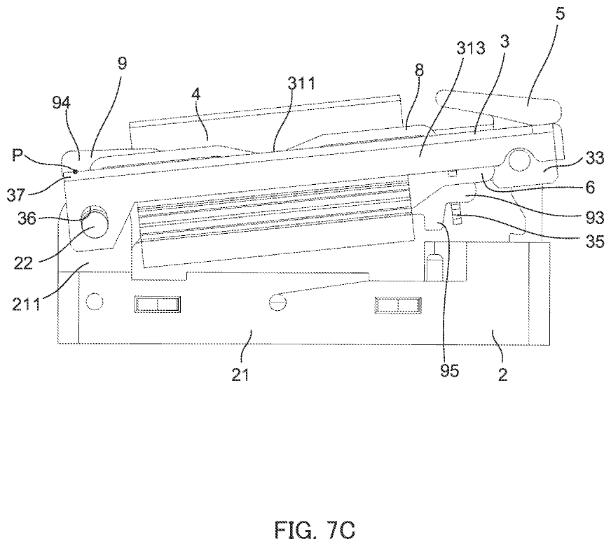

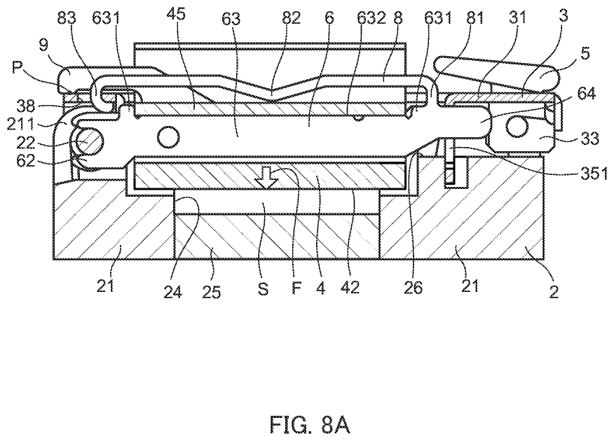

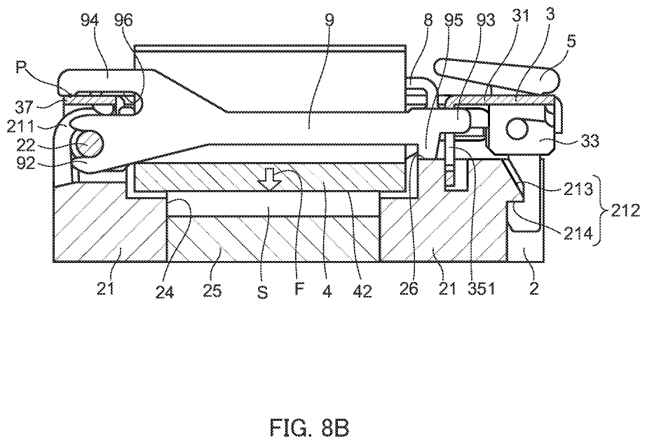

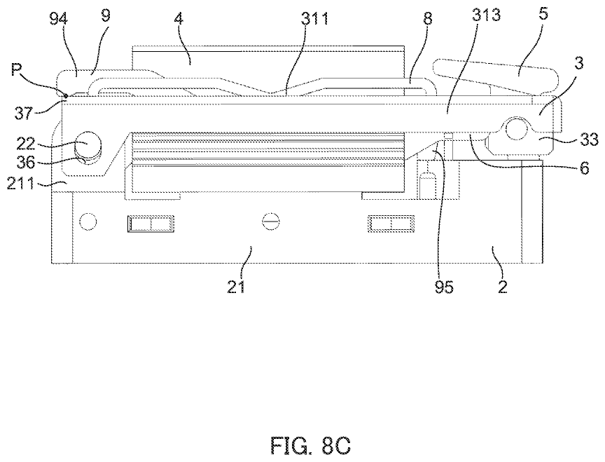

FIGS. 6A to 6C illustrate inspection socket 1 when the opening degree of opening/closing part 3 is 100° (in an opened position), and are a cross-sectional view taken along line C-C of FIG. 2, a cross-sectional view taken along line D-D of FIG. 2, and a side view, respectively. FIGS. 7A to 7C illustrate inspection socket 1 when the opening degree of opening/closing part 3 is 6°, and are a cross-sectional view taken along line C-C of FIG. 2, a cross-sectional view taken along line D-D of FIG. 2, and a side view, respectively. FIGS. 8A to 8C illustrate inspection socket 1 when the opening degree of opening/closing part 3 is 0° (in a closed position), and are a cross-sectional view taken along line C-C of FIG. 2, a cross-sectional view taken along line D-D of FIG. 2, and a side view, respectively. FIGS. 6A to 8C illustrate inspection socket 1 whose opening degree is 6°, and inspection socket 1 whose opening degree is 100° with a proviso that the opening angle of opening/closing portion 3 in the closed position is 0°; however, the opening degrees of 6° and 100° are examples and the opening degree can be changed as appropriate.

Inspection socket 1 is used for inspecting the electrical characteristics of object to be inspected (herein simply referred to as “inspected object”) S (namely, an electronic component, for example, an IC package), which will be described below. Inspection socket 1 includes, for example, base 2 (housing part), opening/closing part 3, latch 5 (locking member), pressing member 4, holding members 6, leaf springs 8, and bails 9 (regulating member). Inspection socket 1 is disposed on a wiring board (not illustrated).

Base 2 includes, for example, body 21, support shaft 22, biasing member 23, recess 24, contact part 25, and part to be abutted (herein simply referred to as “abutted part”) 26.

Body 21 is a frame that constitutes an outer peripheral portion of base 2, and recess 24 is disposed in the central portion of body 21. Shaft supporting portions 211 are disposed at one end part of body 21, and portion to be locked (herein simply referred to as “locked portion”) 212 is disposed at the other end part on the opposite side. In the present embodiment, two shaft supporting portions 211 are provided and one locked portion is provided, but the numbers of the portions can be appropriately changed. Support shaft 22 is inserted through shaft supporting portions 211 and supported by the shaft supporting portions, and latch 5 is locked with locked portion 212. Locked portion 212 includes slope 213 and surface to be locked (herein simply referred to as “locked surface”) 214. Latch 5 moves on slope 213 to be locked with locked surface 214, thereby locking opening/closing part 3 to base 2.

Support shaft 22 is inserted through two shaft supporting portions 211 described above to be supported at both ends. In other words, support shaft 22 is disposed at a fixed position with respect to base 2. Support shaft 22 is inserted through biasing member 23 and holds the biasing member. Support shaft 22 rotatably supports opening/closing part 3, holding member 6, and bail 9.

Biasing member 23 applies an urging force that urges opening/closing part 3 in the opening direction. As an example, a torsion coil spring is used as biasing member 23, but any biasing member having an equivalent function may be used.

Recess 24 is capable of housing inspected object S inside. The opening of recess 24 is opened and closed by opening/closing part 3, and when opening/closing part 3 is in the closed position, opening/closing part 3 presses inspected object S via pressing member 4.

Contact part 25 is disposed at the bottom portion of recess 24, and to be electrically connected with inspected object S and also with the wiring board. Contact part 25 is provided with a plurality of contact pins (not illustrated) according to the configuration of the electrical terminals of inspected object S. At the time of inspecting the inspected object S, inspected object S is placed on contact part 25 in recess 24, and pressing member 4 presses inspected object S. As a result, the electrical terminal of inspected object S comes into contact with the contact pin, the contact pin comes into contact with a connection terminal (not illustrated) disposed on the wiring board to establish the electrical connection between inspected object S and the wiring board without fail.

Abutting part (part for abutting) 95 of bail 9 abuts on abutted part 26. When abutting part 95 abuts on abutted part 26, the movement of bail 9 in the closing direction is stopped, thereby determining the position of regulating part 94 of bail 9. As abutted part 26, any part of body 21 may be used as long as the part is following features: located at a position opposite from regulating part 94 of bail 9 with respect to support shaft 22; and capable of stopping the movement of bail 9 in the closing direction. The detailed configuration of bail 9 will be described below with reference to FIGS. 6B, 7B, and 8B.

Opening/closing part 3 includes, for example, cover 31, supported parts 32, latch supporting plates 33, opening 34, holding plate 35, support shaft holes 36 (loose insertion part), part to be regulated (hereinafter simply referred to as “regulated part”) 37, and insertion holes 38. Opening/closing part holds pressing member 4.

Opening/closing part 3 uses pressing member 4 to open and close the opening of recess 24, and when opening/closing part 3 is in the closed position, the opening/closing part presses inspected object S in recess 24 in the pressing direction F (see, FIGS. 8A and 8B). In the present embodiment, the pressing direction F is perpendicular to the bottom surface of recess 24 and/or to the surface of inspected object S in recess 24. Pressing inspected object S in such a pressing direction F electrically connects inspected object S with the wiring board without fail. The pressing direction F being perpendicular to the surface of inspected object S or the bottom surface of recess 24 is not an essential feature. The pressing direction F may be any direction as long as the pressing force in the pressing direction F does not cause inspected object S to be displaced on the bottom surface of recess 24.

Cover 31 extends in the longitudinal direction, which is orthogonal to the axial direction of support shaft 22, from first end part 311 on the supported part 32 side to the second end part 312 on the side opposite to the first end part. Cover 31 is a frame that constitutes the outer peripheral portion of opening/closing part 3, and opening 34 is disposed in the central portion of cover 31. Cover 31 is rotatably supported by support shaft 22 and is configured to cover the surface of base 2—the surface is on the side where recess 24 is provided—when opening/closing part 3 is in the closed position. Hereinafter, the support shaft direction refers to the axial direction of support shaft 22, and the longitudinal direction refers to a direction orthogonal to the support shaft direction.

When opening/closing part 3 is in the closed position, cover 31 is locked to base 2 at second end part 312 by latch 5 provided on second end part 312. Cover 31 includes, at both end parts thereof in the rotation axis direction, side surface portions 313 each extending in the longitudinal direction and facing standing wall part 44 that is an outer peripheral portion of pressing member 4. Side surface portion 313 is disposed in such a way that standing wall part 44 is exposed to the outside of inspection socket 1. To achieve this configuration, side surface portion 313 is disposed so as to form a gap between side surface portion 313 and base 2 when opening/closing part 3 is in the closed position.

Supported parts 32 are disposed at end parts of cover 31—the end parts are located at both ends in the rotation axis direction of support shaft 22 on the support shaft 22 side. Supported part 32 is rotatably supported by support shaft 22 and support shaft hole 36.

Latch supporting plates 33 are composed of a pair of flat plates located at an end part, on the side opposite to the support shaft 22 side, in cover 31. Each latch supporting plate 33 is disposed so as to extend in a direction perpendicular to upper surface 314 of cover 31. The pair of latch supporting plates 33 rotatably supports latch 5.

Opening 34 is an opened portion provided in the central portion of cover 31. Pressing member 4, holding members 6, leaf springs 8, and bails 9 are disposed in opening 34.

Holding plate 35 holds held part 64 of holding member 6 and held part 93 of bail 9 in such a way that the held parts are relatively movable in the direction, in which opening/closing part 3 opens or closes, within the range of holding groove 351 of the holding plate. Holding plate 35 is a flat plate disposed on the second end part 312 side so as to extend in a direction perpendicular to the upper surface 314 of cover 31. As illustrated in FIG. 5, holding plate 35 includes holding grooves 351 at both ends thereof in the support shaft direction. Holding groove 351 includes first holding portion 352 on the cover 31 side and second holding portion 353 on the body 21 side. First holding portion 352 has an L-shape that extends outward in the support shaft direction and bends toward the body 21 side, and second holding portion 353 has a shape that extends outward in the support shaft direction. A space between first holding portion 352 and second holding portion 353 serves as holding groove 351. Held part 64 of holding member 6 and held part 93 of bail 9 are inserted through holding groove 351.

Support shaft hole 36 is provided in supported part 32, is formed in an elongated hole longer in the direction along the pressing direction F. Support shaft 22 is loosely inserted through the support shaft hole.

In the configuration described above, opening/closing part 3 is supported in the closing operation thereof as follows. Specifically, when opening/closing part 3 moves from the opened position to a predetermined position located before the closed position, opening/closing part 3 is supported in such a way that, with the urging force from biasing member 23, the position of support shaft hole 36 with respect to support shaft 22 does not change. During this operation, opening/closing part 3 is rotationally moved about support shaft 22 by support shaft 22, biasing member 23, and support shaft holes 36 in such a way that the angle between opening/closing part 3 and the pressing direction F changes as the opening/closing part moves. In the present embodiment, the predetermined position is the position of opening/closing part 3 when abutting part 95 of bail 9 comes into contact with abutted part 26 of base 2.

On the other hand, when opening/closing part 3 moves from the predetermined position to the closed position, opening/closing part 3 is supported in such a way that, with the effect of bail 9, the position of support shaft hole 36 with respect to support shaft 22 changed in a direction along the pressing direction F as described in detail below. During this operation, the force for locking opening/closing part 3 by latch 5 is utilized to move opening/closing part 3 along the pressing direction F. This configuration can move pressing member 4 in the pressing direction F to perpendicularly press the surface of inspected object S. The change of the position of support shaft hole 36 with respect to support shaft 22 will be described below with reference to FIGS. 7A to 8C.

Regulated part 37 is a portion of the frame of cover 31—the portion is at the end on the support shaft 22 side. The regulated part is disposed at a position far from recess 24 compared to support shaft hole 36, and rotationally moves in accordance with the rotational movement of cover 31. When opening/closing part 3 moves from the predetermined position to the closed position, the movement of the rotational movement is restricted by regulating part 94 of bail 9. In addition, when opening/closing part 3 is locked with the use of latch 5, regulated part 37 moves opening/closing part 3 toward the base 2 side with the contact point P between regulated part 37 and regulating part 94 serving as a fulcrum for changing the position of support shaft hole 36 with respect to support shaft 22.

Insertion hole 38 is provided in regulated part 37, and is formed in an elongated hole longer in the longer direction of leaf spring 8 as illustrated in FIGS. 6A, 7A, and 8A. Distal end part 83 of leaf spring 8 is inserted through insertion hole 38, allowing the through insertion hole to hold the leaf spring 8.

Pressing member 4 includes, for example, pressing member main body 41, pressing surface 42, lower flanges 43, standing wall parts 44, and upper flanges 45 (longitudinal part), upper fins 46, and side fins 47 (pressing member protrusion). Pressing member 4 is disposed by holding member 6 in opening 34 located between first end part 311 and second end part 312.

Pressing member main body 41 is a main body portion of pressing member 4, and the bottom portion thereof serves as pressing surface 42. When opening/closing part 3 is in the closed position, pressing surface 42 presses inspected object S placed on contact part 25 in the pressing direction F. Pressing the inspected object S by pressing member 4 electrically connects inspected object S with the wiring board via contact part 25 without fail.

Pressing member main body 41 includes, at both end parts thereof in the rotation axis direction, lower flanges 43, standing wall parts 44, and upper flanges 45 each disposed so as to extend in the longitudinal direction along holding member 6. Lower flange 43 is provided so as to protrude outward in the rotation axis direction from the end part of pressing member main body 41 in the rotation axis direction. Standing wall part 44 is erected from the outer edge portion of lower flange 43. Upper flange 45 is provided so as to protrude inward in the rotation axis direction from standing wall part 44. In other word, lower flange 43, standing wall part 44, and upper flange 45 form a U-shaped cross section in the rotation axis direction. The lower surface of the upper flange 45 is provided along the longitudinal direction, and is disposed to face supporting part 63 so as to function as a portion supported by supporting part 63.

Standing wall part 44 and pressing member main body 41 facing standing wall part 44 are disposed so as to face each other in the rotation axis direction with holding member 6 placed therebetween. This configuration allows standing wall part 44 and pressing member main body 41 to function as movement regulating parts for regulating the movement of holding member 6 in the rotation axis direction. Holding member 6 is surrounded by standing wall part 44 and pressing member main body 41, thus it is possible to prevent holding member 6 from falling off outward in the rotation axis direction. In addition, the width between standing wall part 44 and pressing member main body 41 can be reduced, and in this case, the expansion of the lateral width of inspection socket 1 can be prevented.

Upper fin 46 and side fin 47 are also disposed so as to extend in the longitudinal direction in the same manner as lower flange 43, standing wall part 44, and upper flange 45. Upper fin 46 is provided so as to protrude upward from the upper portion of pressing member main body 41, thereby protruding from upper surface 314 of cover 31 to the outside of inspection socket 1. In addition, side fin 47 is provided so as to protrude outward in the rotation axis direction from the end part of standing wall part 44, thereby being inserted through the gap between side surface portion 313 of cover 31 and base 2 to protrude from standing wall part 44 to the outside of inspection socket 1.

Pressing member 4 having such a configuration takes heat from inspected object S when coming into contact with inspected object S, and releases the taken heat from plurality of upper fins 46 and side fins 47 to the surroundings. Pressing member 4 thus functions as a heat dissipation member to maintain the temperature of inspected object S at a predetermined value. It is not necessary to increase the height of cover 31 in the present embodiment, and thus the heat dissipation performance can be further improved by exposing upper fins 46 and side fins 47 or disposing the fins so as to protrude to the outside of cover 31. In the present embodiment, pressing member 4 also serves as a heat radiating member, thus includes plurality of upper fins 46 and side fins 47, but when the function as a heat radiating member is unnecessary, upper fins 46 and side fins 47 may be omitted.

Further, the use of holding member 6 eliminates the necessity for processing of providing a hole for the shaft in pressing member 4; therefore, pressing member 4 can be formed by extrusion processing. As a result, the manufacturing cost of pressing member 4 is reduced, and the degree of freedom in processing is increased.

Latch 5 is provided at cover 31 on the second end part 312 side in the longitudinal direction. When opening/closing part 3 is brought into the closed position, latch 5 is pushed toward the base 2 side to lock opening/closing part 3 with base 2. Latch 5 is rotatably attached between the pair of latch supporting plates 33, and when opening/closing part 3 is in the closed position, the latch is locked to locked portion 212 of base 2. In the closed position, latch 5 is urged by a biasing member, such as a torsion coil spring (not illustrated), provided on latch 5 so that the locked state to locked portion 212 is maintained. As described below, an external force that pushes latch 5 toward the base 2 side for locking is used to change the position of support shaft hole 36 with respect to support shaft 22 with the contact point P as a fulcrum.

As illustrated in FIGS. 2, 6A, 7A and 8A, holding member 6 includes, for example, holding member main body 61, supported part 62 (notched part), supporting part 63 (pressing member supporting part), and held part 64 (extension part). Holding member 6 is extended in a bridge form between cover 31 and pressing member 4. This configuration allows holding member 6 to hold pressing member 4 in such a way that pressing member 4 rotatably moves together with cover 31, and to movably hold pressing member 4 in such a way that pressing surface 42 follows the surface of inspected object S when pressing member 4 comes into contact with inspected object S. In the present embodiment, two holding members 6 are provided, but the number and the disposed position in the axial direction can be appropriately changed. When the number or disposed position of holding members 6 is changed, the numbers or disposed positions of lower flanges 43, standing wall parts 44, and upper flanges 45 of pressing member 4 may be changed so as to correspond to this change.

Holding member main body 61 is a flat plate-shaped member extending in the longitudinal direction. The flat surface of holding member main body 61 is disposed so as to face standing wall part 44.

Supported part 62 is provided at a base end part, which is located on the first end part 311 side in the longitudinal direction, in holding member main body 61. Supported part 62 is formed in a notched shape in such a way that support shaft 22 is detachably fitted thereto, for example, in a U-shape or a C-shape, and is rotatably supported by support shaft 22. Since supported part 62 is formed in such a shape, the supported part can be easily replaced for changing the size of holding member 6 depending on the shape (for example, thickness) of inspected object S.

Supporting part 63 is a portion of holding member main body 61 and supports upper flange 45 of pressing member 4. The supporting part is disposed between supported part 62 and held part 64. When pressing member 4 comes into contact with inspected object S due to the rotational movement of opening/closing part 3 in the closing direction, pressing member 4 receives a reaction force from inspected object S. Supporting part 63 supports upper flange 45 from the closed position side in such a way that at least a part thereof can be separated from upper flange 45 due to the reaction force accompanying the contact. Supporting part 63 includes protrusions 631 (holding member protrusions), each protruding toward the opened position side, on both sides in the longitudinal direction. Supporting part 63 and protrusions 631 form housing groove 632 for housing upper flange 45. Protrusions 631 guide pressing member 4 to house upper flange 45 in housing groove 632, and regulates the position of upper flange 45 to position pressing member 4, thereby preventing the shift of pressing member 4 in the longitudinal direction.

Held part 64 is provided at a distal end part located on the second end part 312 side in the longitudinal direction, and is provided so as to extend in the longitudinal direction from supporting part 63. Held part 64 is inserted through holding groove 351 of holding plate 35. As held part 64 can move within the range inside holding groove 351, holding member 6 can rotate with respect to opening/closing part 3 within an angle range corresponding to the range inside holding groove 351.

In the present embodiment, holding member 6 extending in the longitudinal direction holds pressing member 4, thus it is not necessary to increase the height of side surface portion 313 of cover 31. Therefore, the reduction of the height of opening/closing part 3 and thus of inspection socket 1 becomes possible.

In addition, in the present embodiment, holding member 6 is extended in a bridge form between cover 31 and pressing member 4, and thus the orientation of pressing member 4 can be adjusted in such a way that pressing member 4 can be separated from holding member 6 and pressing surface 42 becomes parallel to the surface of inspected object S at the time of contact with inspected object S.

Holding member 6 has a flat plate shape, which makes easy to manufacture the holding member by press working, and also to change the shape of the holding member. For example, for changing the pressing distance of pressing member 4, or pressing the pressing member 4 in an inclined posture depending on the shape of inspected object S, the holding member may have a shape such that held part 64 or housing groove 632 has a different position or inclination with respect to opening/closing part 3 in the closed position.

As illustrated in FIGS. 2, 6A, 7A and 8A, leaf spring 8 is a flat plate-shaped member disposed so as to extend in the longitudinal direction in such a way that the leaf spring is disposed in the longitudinal direction along holding member 6. The leaf spring includes, for example, base end part 81 (leaf spring base end part), pressing part 82 (leaf spring intermediate part), and distal end part 83 (leaf spring distal end part). Leaf spring 8 is integrally connected to holding member 6 and rotates together with cover 31. Leaf spring 8 holds pressing member 4 in such a way that pressing member 4 is separable from holding member 6 except during latching of opening/closing part 3, and presses pressing member 4 during latching of opening/closing part 3.

Base end part 81 is disposed in leaf spring 8 on the second end part 312 side in the longitudinal direction. Base end part 81 is connected to holding member 6 at a position in the second end part 312 side in the longitudinal direction. Leaf spring 8 is composed of a plate-shaped member the same as that of holding member main body 61, and is provided as a branch from holding member main body 61. This configuration makes holding member 6 and leaf spring 8 integrated into one member.

Pressing part 82 is disposed in an intermediate portion between base end part 81 and distal end part 83 in leaf spring 8. The pressing part presses the upper surface of upper flange 45 when leaf spring 8 is elastically deformed, and exerts a pressing force on pressing member 4. Pressing part 82 has a dogleg shape bent toward the upper flange 45 side of pressing member 4. During latching of opening/closing part 3, pressing part 82 presses the center of the upper surface of upper flange 45. On the other hand, pressing part 82 does not come into contact with the upper surface of upper flange 45 except during latching. Pressing part 82 is not in contact with the upper surface of upper flange 45 as described above, thus upper flanges 45 can move in the space between supporting part 63 of holding member 6 and pressing part 82 of leaf spring 8. In addition, forming pressing part 82 into a dogleg shape allows both ends of upper flange 45 in the longitudinal direction to move (incline) largely.

Distal end part 83 is disposed in leaf spring 8 on the first end part 311 side in the longitudinal direction. Distal end part 83 is inserted through insertion hole 38 formed in cover 31 and engaged with cover 31. In addition, distal end part 83 has a hook-like shape. When pressing part 82 presses the upper surface of upper flange 45, distal end part 83 can move in the longitudinal direction along the elongated hole of insertion hole 38 in accordance with the elastic deformation. Distal end part 83 has a configuration such that the distal end part can move in the direction along the elongated hole, but has a hook-like shape at its tip to be engaged with cover 31, thereby supporting pressing part 82 from both ends, namely base end part 81 and distal end part 83, with respect to the pressing direction F toward pressing member 4.

In the present embodiment, pressing member 4 is pressed by using leaf spring 8, and thus changing the material and thickness of leaf spring 8 allows for setting of the pressing condition by the bending of leaf spring 8 only, and changing of the pressing force for pressing member 4 to a desired pressing force is also easy. In addition, pressing part 82 presses the center of upper flange 45 as described above, thus the pressing of pressing member 4 can be performed independently of the inclination and shape of pressing member 4.

In conventional sockets, a cam or the like performs the pressing. Therefore, such conventional sockets have disadvantages such as a large number of parts, difficulty in changing the pressing setting of the pressing member, unintentional inclining of a pressing member, and rubbing of an inspected object.

In the present embodiment, on the other hand, pressing member 4 is pressed by using leaf spring 8, and thus changing the material and thickness of leaf spring 8 allows for setting of the pressing condition by the bending of leaf spring 8 only, and changing of the pressing force for pressing member 4 to a desired pressing force is also easy.

As illustrated in FIGS. 2, 6B, 7B and 8B, bail 9 is also a flat plate-shaped member disposed so as to extend in the longitudinal direction, and includes, for example, bail main body 91, supported part 92 (supported part in a regulating member), held part 93, regulating part 94, abutting part 95, and notched part 96. Bail 9 rotates together with opening/closing part 3, and when opening/closing part 3 is in the closed position, the bail also regulates the movement of regulated part 37. In the present embodiment, two bails 9 are provided, but the number and the disposed position in the axial direction can be appropriately changed. When the number or disposed position of bails 9 is changed, the number or disposed position of upper flanges 45 of pressing member 4 may be changed so as to correspond to this change.

Bail 9 is in contact with regulated part 37, and rotationally moves in accordance with the rotational movement of regulated part 37 in the closing direction, that is, with the rotational movement of opening/closing part 3 in the closing direction. When opening/closing part 3 moves from a predetermined position to the closed position, regulating part 94 regulates the rotational movement of regulated part 37. During the movement, the position of support shaft hole 36 with respect to support shaft 22 changes with the contact point P, where regulating part 94 contacts regulated part 37, as a fulcrum. The configuration of such bail 9 will be described below.

Supported part 92 is provided at an end part, which is located on the support shaft 22 side, in bail main body 91. Supported part 92 is formed in a shape in such a way that support shaft 22 is detachably fitted thereto, for example, in a U-shape or a C-shape, and is rotatably supported by support shaft 22. As with supported part 62 of holding member 6, supported part 92 is formed in the above described shape and thus can be attached to and detached from support shaft 22. Therefore, the supported part can be easily replaced for changing the size of bail 9 depending on the shape (for example, thickness) of inspected object S.

Held part 93 is provided at an end part of bail main body 91—the end part located opposite to the support shaft 22 side, and is inserted through holding groove 351 of holding plate 35. As held part 93 can move within the range inside holding groove 351, bail 9 can rotate within an angle range corresponding to the range inside holding groove 351.

Regulating part 94 is disposed so as to come into contact with regulated part 37 when opening/closing part 3 is in the closing operation. For this configuration, regulating part 94 is disposed in bail 9 on the support shaft 22 side, but at a position different from that of supported part 92, specifically, at a position far from recess 24 compared to supported part 92 and regulated part 37. In the present embodiment, as an example, regulating part 94 is provided so as to branch off from supported part 92, and supported part 92 and regulating part 94 form a Y shape. Notched part 96 is formed between supported part 92 and regulating part 94, and regulated part 37 of opening/closing part 3 is disposed in notched part 96.

The disposition described above allows the movement of opening/closing part 3 in the pressing direction F by placing the contact point P at a position far from recess 24 compared to support shaft 22, and changing the position of support shaft hole 36 with respect to support shaft 22 with the contact point P as a fulcrum.

Regulating part 94 comes into contact with regulated part 37 when opening/closing part 3 is in the closing operation, thus bail 9 itself rotationally moves about support shaft 22 in accordance with the rotational movement of opening/closing part 3. On other hand, during the closing operation of opening/closing part 3, abutting part 95 serves as a stopper and regulating part 94 becomes immovable when opening/closing part 3 moves from the predetermined position to the closed position as described below.

Abutting part 95 is provided on the opposite side of regulating part 94 with respect to support shaft 22. As an example, in the present embodiment, abutting part 95 is provided adjacent to held part 93 and has a convex shape extending toward the body 21 side. As described above, bail 9 rotationally moves in accordance with the rotational movement of opening/closing part 3, causing abutting part 95 to rotationally move; however, when opening/closing part 3 moves from the predetermined position to the closed position, the abutting part abuts on abutted part 26 of base 2. When opening/closing part 3 moves from the predetermined position to the closed position, abutting part 95 becomes immovable because the abutting part abuts on abutted part 26. In addition, as abutting part 95 serves as a stopper, regulating part 94 also becomes immovable. As a result, regulating part 94 regulates the rotational movement of regulated part 37 in the closing direction.

In the present embodiment, shaft supporting portions 211, support shaft 22, and bail 9 form a supporting part that supports supported part 32 and support shaft hole 36 of opening/closing part 3. Such a configuration allows body 21 to support opening/closing part 3 on one side thereof in such a way that opening/closing part 3 is movable between the opened position and the closed position.

Movement in Inspection Socket

The movements of bail 9 and opening/closing part 3 in inspection socket 1 together with the movements of holding member 6 and leaf spring 8 will be described with reference to FIGS. 6A to 8C.

Inspection socket 1 with opening/closing part 3 whose opening degree is 100° will be described with reference to FIGS. 6A to 6C. As described above, holding member 6 is rotatable within an angle range corresponding to the range inside holding groove 351. Leaf spring 8 is integrally connected to holding member 6 and can rotate together when opening/closing part 3 has an opening degree of 100° (see FIG. 6A). At this point, pressing part 82 of leaf spring 8 does not press upper flange 45 of pressing member 4, and pressing member 4 is not in contact with inspected object S. Pressing member 4 with upper flange 45 disposed between holding member 6 and leaf spring 8 is thus in a state where the pressing member can be separated from holding member 6 when a force is applied in the opening direction.

As illustrated in FIG. 6B, regulating part 94 of bail 9 in this state is in contact with regulated part 37 of cover 31. Regulating part 94 thus rotationally moves in accordance with the rotational movement of opening/closing part 3 in the closing direction.

In addition, cover 31 is urged in the opening direction by biasing member 23, and thus support shaft 22 in support shaft hole 36 is located at a position away from upper surface 314 of cover 31 as illustrated in FIG. 6C.

Inspection socket 1 with opening/closing part 3 whose opening degree is 6° will be described with reference to FIGS. 7A to 7C. When opening/closing part 3 has an opening degree of 6° during the moving of opening/closing part 3 in the closing direction, the tip of latch 5 comes into contact with slope 213 of locked portion 212 as illustrated in FIG. 7B. Held part 64 of holding member 6 is held in holding groove 351, and upper flange 45 of pressing member 4 is disposed between holding member 6 and leaf spring 8. Holding member 6 and pressing member 4 thus move in the closing direction together with opening/closing part 3. When the opening degree is 6°, pressing member 4 is also in a state where the pressing member can be separated from holding member 6, and is not in contact with inspected object S as in the case of the opening degree of 100°. As the opening degree of opening/closing part 3 decreases, upper flange 45 of pressing member 4 starts to enter housing groove 632 to be housed therein due to the weight of pressing member 4.

As illustrated in FIG. 7B, regulating part 94 of bail 9 in this state is also in contact with regulated part 37 of cover 31, and rotationally moves in the closing direction together with opening/closing part 3 when the opening degree is 6°, as in the case of the opening degree of 100°.

In addition, cover 31 is urged in the opening direction by biasing member 23, and thus support shaft 22 in support shaft hole 36 is located at a position away from upper surface 314 of cover 31 as illustrated in FIG. 7C.

When opening/closing part 3 is further moved in the closing direction, a part of pressing surface 42 of pressing member 4 starts to come into contact with inspected object S, but until upper flange 45 is pressed by pressing part 82, pressing member 4 is still in a state where the pressing member can be separated from holding member 6 as in the case of the opening degree of 6°. Therefore, when a part of pressing surface 42 of pressing member 4 comes into contact with inspected object S, pressing member 4 inclines in such a way that pressing surface 42 becomes parallel to the surface of inspected object S due to the reaction force accompanying the contact. At this time, upper flange 45 is housed inside housing groove 632, and thus pressing member 4 inclines in such a way that pressing surface 42 becomes parallel to the surface of inspected object S within the range in which upper flange 45 does not deviate from housing groove 632 because of protrusions 631.

Further moving of opening/closing part 3 in the closing direction allows abutting part 95 of bail 9 to abut abutted part 26 of body 21. At this time, regulating part 94 of bail 9 is in contact with regulated part 37 of cover 31; however, abutting part 95 of bail 9 abuts on abutted part 26, allowing the abutting part to serve as a stopper, and thus the position of regulating part 94 with respect to support shaft 22 does not change any more. In other words, regulating part 94 not only contacts regulated part 37 but also regulates the movement of the regulated part in the closing direction.

Inspection socket 1 with opening/closing part 3 whose opening degree is 0° will be described with reference to FIGS. 8A to 8C. When opening/closing part 3 is further moved in the closing direction, the opening degree of opening/closing part 3 becomes 0°, and as illustrated in FIG. 8B, latch 5 is locked to locked surface 214 of locked portion 212 (latch 5 is in a locked state). At this time, pressing part 82 of leaf spring 8 presses upper flange 45 of pressing member 4. Leaf spring 8 in this state perpendicularly presses the surface of inspected object S via pressing member 4 because pressing surface 42 is made parallel to the surface of inspected object S as described above. This configuration allows pressing member 4 to perpendicularly press the surface of inspected object S due to the pressing force via cover 31 and leaf spring 8.

At this time, regulating part 94 of bail 9 is also in contact with regulated part 37 of cover 31. Abutting part 95 of bail 9 abuts on abutted part 26, and thus the position of regulating part 94 with respect to support shaft 22 does not change.

In addition, opening/closing part 3 is urged in the opening direction by biasing member 23. When opening/closing part 3 is locked with the use of latch 5, the position of support shaft hole 36 with respect to support shaft 22 is changed in the direction along the pressing direction F by using the force applied to latch 5 against this urging force. Specifically, an external force that pushes latch 5 toward the base 2 side for locking is used to change the position of support shaft hole 36 in the direction along the pressing direction F with respect to support shaft 22 with the contact point P between regulating part 94 and regulated part 37 as a fulcrum. As a result, both the support shaft hole 36 side and the latch 5 side of cover 31 are moved in the direction along the pressing direction F. Therefore, as illustrated in FIG. 8C, the position of support shaft 22 in support shaft hole 36 is now on the upper surface 314 side of opening/closing part 3. In this way, opening/closing part 3 is pressed by latch 5 at one end part thereof and by regulating part 94 of bail 9 at the other end part thereof. Therefore, pressing member 4 is in a state of perpendicularly pressing the surface of inspected object S due to the pressing force via opening/closing part 3 and leaf spring 8.

When opening/closing part 3 moves from the opened position to the predetermined position, opening/closing part 3 is urged in the opening direction by biasing member 23. Opening/closing part 3 thus rotationally moves about support shaft 22 as a rotation axis during this movement. On the other hand, when opening/closing part 3 moves from the predetermined position to the closed position, opening/closing part 3 rotationally moves about the contact point P as a rotation axis because the position of support shaft hole 36 with respect to support shaft 22 can change, and bail 9 acts as a stopper. This means that the rotation axis of opening/closing part 3 moves away from recess 24 toward the distal side. When the rotation axis of opening/closing part 3 moves away toward the distal side, the curvature of rotation of opening/closing part 3 becomes small (curve becomes gentle). The orbit of the movement of opening/closing part 3 thus changes from a curved line to an approximate straight line parallel to the pressing direction F. That is, opening/closing part 3 moves along the pressing direction F. In the present embodiment, the movement from the predetermined position to the closed position, that is, the movement along the pressing direction F is not a straight line but a curved line. As described above, the curvature of the orbit of the movement from the predetermined position to the closed position is changed so as to become smaller than that of the movement from the open position to the predetermined position. Therefore, the curvature of the orbit of the movement from the predetermined position to the closed position may be set to zero, and thus the movement from the predetermined position to the closed position may be a linear movement parallel to the pressing direction F.

In the present embodiment, the predetermined position is the position of opening/closing part 3 when abutting part 95 comes into contact with abutted part 26 of base 2 as described above. However, the timing at which opening/closing part 3 reaches the predetermined position does not have to be the timing at which abutting part 95 comes into contact with abutted part 26 of base 2. What is essential is the presence of a position where the orbit of the movement of opening/closing part 3 is switched or changed during the movement of opening/closing part 3 from the opened position to the closed position. This position, where the switching or changing takes place, is the predetermined position.

In inspection socket 1 of the present embodiment, latch 5 and regulating part 94 of bail 9 press both ends of opening/closing part 3 when opening/closing part 3 is locked with the use of latch 5 as described above. This configuration allows pressing member 4 to perpendicularly press the surface of inspected object S when pressing inspected object S, thereby preventing the damage of the surface of inspected object S which would be caused by lateral shifting of inspected object S.

In the conventional inspection socket employing the pressing method by a cam member, pressing by the cam member is required in addition to a latch, which requires at least two operations for the user. In the present embodiment, on the other hand, simply locking opening/closing part 3 to the body 21 side with the use of latch 5 can simultaneously perform pressing by pressing member 4. Simply one operation thus can achieve both locking and pressing, which can reduce the burden on the user.

In addition, subsequent attaching of bail 9 to the existing socket can obtain working effects the same as those described above. Further, for inspected object S having a different size, simply replacing bail 9 with another bail 9 having the size corresponding to the different size can handle the size difference of inspected object S.

Using holding member 6 and leaf spring 8 as described above in the present embodiment can also provide the following effects.

Holding member 6 and leaf spring 8 hold pressing member 4 in such a way that pressing member 4 is separable from holding member 6 except during the pressing. Therefore, when pressing member 4 comes into contact with inspected object S, pressing member 4 can be inclined in such a way that pressing surface 42 becomes parallel to the surface of inspected object S. As a result, pressing member 4 can perpendicularly press the surface of inspected object S when pressing inspected object S, thereby preventing the damage of the surface of inspected object S, which would be caused by lateral shifting of inspected object S.

In addition, pressing member 4 is pressed by using leaf spring 8, and thus changing the material and thickness of leaf spring 8 allows for setting of the pressing condition by the bending of leaf spring 8 only, and allows for changing of the pressing force for pressing member 4 to a desired pressing force. Further, pressing part 82 presses the center of upper flange 45, thus the pressing of pressing member 4 can be performed independently of the inclination and shape of pressing member 4.

No shaft is provided in inspection socket 1, which eliminates the necessity of providing a hole for the shaft in pressing member 4, thereby reducing the manufacturing cost of the inspection socket. Holding member 6 is formed by press working, which can significantly reduce the manufacturing cost of the holding member.

The use of no shaft can lead to the decrease of the thickness of opening/closing part 3. When the pressing member also functions as a heat sink, more efficient heat dissipation can be obtained.

As holding member 6 is provided inside opening 34 of opening/closing part 3, even if holding member 6 comes off from support shaft 22, the falling range would be inside inspection socket 1 and not on the wiring board. There is thus no risk of short circuit on the wiring board.

Holding member 6 is formed by press working, which makes easy to change its shape. For inspected object S having a different size, simply replacing holding member 6 with another holding member 6 having the size corresponding to the different size can handle the size difference of inspected object S.

The above-described embodiments are merely examples of embodiments in implementing the invention, and the technical scope of the invention should not be interpreted in a limited manner by these examples. In other words, the present invention can be implemented in various ways without deviating from its scope or its main features.

The disclosures of Japanese Patent Application No. 2019-186555, filed on Oct. 10, 2019, including the specification, drawings and abstract, is incorporated herein by reference in its entirety.

### INDUSTRIAL APPLICABILITY

The present invention is suitably used for sockets for inspecting electronic components.

### REFERENCE SIGNS LIST

1 Inspection socket
2 Base
21 Body
211 Shaft supporting portion
212 Locked portion
213 Slope
214 Locked surface
22 Support shaft
23 Biasing member
24 Recess
25 Contact part
26 Abutted part
3 Opening/closing part
31 Cover
311 First end part
312 Second end part
313 Side surface portion
314 Upper surface
32 Supported part
33 Latch supporting plate
34 Opening
35 Holding plate
351 Holding groove
352 First holding portion
353 Second holding portion
36 Support shaft hole
37 Regulated part
38 Insertion hole
4 Pressing member
41 Pressing member main body
42 Pressing surface
43 Lower flange
44 Standing wall part
45 Upper flange
46 Upper fin
47 Side fin
5 Latch
6 Holding member
61 Holding member main body
62 Supported part
63 Supporting part
631 Protrusion
632 Housing groove
64 Held part
8 Leaf spring
81 Base end part
82 Pressing part
83 Distal end part
9 Bail
91 Bail main body
92 Supported part
93 Held part
94 Regulating part
95 Abutting part
96 Notched part
F Pressing direction
P Contact point
S Inspected object

1. A socket comprising:
a housing part including a recess configured to house an electronic component;
an opening/closing part that opens and closes an opening of the recess, and presses the electronic component in the recess in a pressing direction when the opening/closing part is in a closed position; and
a supporting part that supports the opening/closing part so as to allow a movement of the opening/closing part between an opened position and the closed position,
wherein
during a closing operation of the opening/closing part, the supporting part supports the opening/closing part in such a way that
when the opening/closing part moves from the opened position to a predetermined position located before the closed position, the movement of the opening/closing part is accompanied by changing of an angle between the pressing direction and the opening/closing part, and
when the opening/closing part moves from the predetermined position to the closed position, the movement of the opening/closing part is along the pressing direction.

2. The socket according to claim 1, wherein:
the opening/closing part includes
a cover supported by the supporting part so as to be openable and closeable, and
a pressing member held by the cover, the pressing member pressing the electronic component in the recess when the opening/closing part is in the closed position; and
during the closing operation of the opening/closing part, the supporting part supports the cover in such a way that
when the opening/closing part moves from the opened position to the predetermined position, a movement of the cover is accompanied by changing of an angle between the pressing direction and the cover, and
when the opening/closing part moves from the predetermined position to the closed position, the movement of the cover is along the pressing direction.

3. The socket according to claim 2, wherein:
the supporting part includes a support shaft that is disposed at a fixed position with respect to the housing part, the support shaft rotatably supporting the cover;
the cover includes a loose insertion part through which the support shaft is loosely inserted; and
the supporting part supports the cover in such a way that
when the opening/closing part moves from the opened position to the predetermined position, a position of the loose insertion part with respect to the support shaft does not change, and
when the opening/closing part moves from the predetermined position to the closed position, the position of the loose insertion part with respect to the support shaft changes.

4. The socket according to claim 3, wherein:
the cover includes a regulated part disposed at a position far from the recess compared to the loose insertion part, the regulated part being caused to perform a rotational movement in accordance with a rotational movement of the cover; and
the supporting part includes a regulating member that regulates the rotational movement of the regulated part and changes the position of the loose insertion part with respect to the support shaft with a contact point as a fulcrum when the opening/closing part moves from the predetermined position to the closed position, the contact point being a point at which the regulating member is in contact with the regulated member.

5. The socket according to claim 4, wherein:
the regulating member includes
a supported part rotatably supported by the support shaft,
a regulating part configured to come into contact with the regulated part and to be caused to perform a rotational movement in accordance with the rotational movement of the regulated part, and
an abutting part provided on a side opposite to the regulating part with respect to the support shaft, the abutting part being caused to perform a rotational movement in accordance with the rotational movement the regulating part, the abutting part abutting on the housing part when the opening/closing part moves from the predetermined position to the closed position; and
when the abutting part abuts on the housing part, the regulating part becomes immovable and restricts the rotational movement of the regulated part.

6. The socket according to claim 5, wherein:
the predetermined position is a position of the opening/closing part when the abutting part comes into contact with the housing part.

7. The socket according to claim 4, further comprising:
a locking member provided at the cover on a side opposite to the regulated part with respect to the support shaft, the locking member locking the cover with the housing part when the opening/closing part is moved to the closed position, wherein
an external force is used to change the position of the loose insertion part with respect to the support shaft with the contact point as the fulcrum, the external force being for locking the locking member with the housing part.

8. The socket according to claim 1, wherein:
the pressing direction is perpendicular to at least one of a bottom surface of the recess and a surface of the electronic component in the recess.

9. An inspection socket comprising:
the socket according to claim 1; and
a contact part disposed in a bottom portion of the recess, the contact part being configured to be electrically connected to the electronic component in the recess, wherein
the inspection socket is used for inspecting electrical characteristics of the electronic component.
